(19) United States
(12) Patent Application Publication
(10) Pub. No.: US 2007/0053166 A1
(43) Pub. Date: Mar. 8, 2007

(54) Heat dissipation device and composite material with high thermal conductivity

(75) Inventors: Jen-Dong Hwang, Hsinchu City (TW); Jiann-Jong Su, Miaoli County (TW); Chih-Jong Chang, Changhua County (TW); Cheng-Chou Wong, Hsinchu County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/453,416

(22) Filed: Jun. 14, 2006

(30) Foreign Application Priority Data
Sep. 8, 2005 (TW) TW94130863

(51) Int. Cl. H05K 7/20

(52) U.S. Cl. 361/717; 361/715

(57) ABSTRACT

A heat dissipation device for an electronic device includes a first heat dissipation element contacting the electronic device, wherein the material of the first heat dissipation element includes a composite material with high thermal conductivity comprising carbon fiber or porous graphite. The material with high thermal conductivity includes a fibrous structure and a matrix.

### BACKGROUND

The present invention is related to a heat dissipation device, and in particular to a heat dissipation device having a heat dissipation element made of composite material with high thermal conductivity and light weight.

To prevent overheating and increase reliability, heat created by electronic devices must be dissipated to the external environment by conduction, convection or radiation. Heat sink is a commonly used heat dissipation device, which is mounted on a surface of an electronic device, such as CPU, VGA card (GPU), BGA (Ball grid array), MCM (multi-chip module) and LED module. A conventional heat sink 120, as shown in FIGS. 1a and 1b, comprises a base plate 104 and a heat dissipation element 120 having a plurality of fins 100. The base plate 104 directly contacts an electronic element (not shown) to remove heat from the electronic element rapidly, and the fins 100 increase the heat dissipation area to further dissipate heat from the base plate 104 to the external environment via convection. The heat sink 120 of FIG. 1b further comprises a heat pipe 102 rapidly transferring heat from the base plate 104 to fins 100. The heat dissipation efficiency increases proportionally with the thermal conductivity and heat dissipation area.

Previous CPU, such as Pentium II or III, generated less heat (less than 80 W) and was dissipated by air-cooled thermal module. The thermal modules used for these CPUs, commonly comprise an aluminum heat dissipation element (heat sink) and a fan. The aluminum heat dissipation element can be manufactured by extrusion, die casting, bonding, folding, forging, stamping, skiving and the like. But as the clock speed and package density of the CPU increases, the heat generated by the CPU also increases (greater than 100 W). As the aluminum heat dissipation elements are insufficient for such a high power density and heat flux, they have been gradually replaced by copper heat dissipation elements whose thermal conductivity is twice of pure aluminum. Copper heat dissipation elements, however, are heavier and difficult to subject to near shape forming and has poor resistance to thermal shock/vibration. In the future, heat generation by electronic elements is expected to keep increasing due to the compact size and high packaging density. Any new heat dissipation material substituting for copper should have high thermal conductivity, high thermal diffusivity, low expansion coefficient as well as low density to meet the requirements of electronic devices.

R.O.C. patent No. 573025 discloses a method of manufacturing a heat sink where copper powder, carbon powder and polymer binder are blended and then processed with heat treatments. The polymer is finally evaporated at high temperature and a carbon-copper composite material with low expansion coefficient is obtained. In this method, however, the volume fraction of reinforced carbon powder can not exceed 30%, thus the thermal conductivity and thermal diffusivity of the composite is thus limited.

R.O.C. patent No. 534374 discloses a heat sink material comprising milled fibers with high thermal conductivity and a polymer matrix. The milled fibers and polymer are homogenously mixed and then are subject to plastic injection molding to form a composite heat sink. However, the thermal performance of this composite is not good enough in that the thermal conductivity of this composite is only equivalent to the level of aluminum.

U.S. Pat. No. 5,981,085 discloses a ceramic powder reinforced aluminum matrix composite and a copper matrix composite with low thermal expansion coefficient and moderate thermal conductivity. The ceramic powders are either SiC, BeO or AlN. This metal matrix composite (MMC) has thermal conductivity of about 180˜220 W/mK which is also approximate to the one of pure aluminum, but has poor workability. This composite materials are employed to use as a heat spreader between a semiconductor chip and a heat dissipation element.

US publication No. 20040175875A1 discloses a diamond composite material which are manufactured by infiltrating molten aluminum or copper into a mold filled with diamond powder at high pressure and high temperature furnace. This diamond composite material even has high thermal conductivity over 500 W/m.K, but is very expensive and difficult to finish and machine.

U.S. Pat. No. 6,469,381 also discloses a composite heat spreader more specially coupled to the integrated circuit for heat dissipation. The composite materials include a metal matrix and high conductive carbon fibers

### SUMMARY

An embodiment of a heat dissipation device of the invention comprises a first heat dissipation element contacting the electronic device. The material of the first heat dissipation element comprises a composite with high thermal conductivity and affordable CTE with semiconductor device. The composite material comprises a fibrous structure and a matrix where the fibrous structure is substantially composed of milled carbon fiber, discontinuous carbon fibers (chopped fiber), continuous carbon fibers and graphite foam. The types of carbon fiber comprise PAN fiber, pitch fiber, vapor grown carbon fiber (VGCF), carbon nanotubes (CNT). The volume percentage of the fibrous structure is between 10% and 90%. The matrix is substantially composed of metal material. The metal matrix can comprise aluminum copper silver zinc magnesium and their alloys thereof. The matrix is composed of carbon material which has precursors of pitch phenolic resin or hydrocarbon gases. The heat dissipation device further comprises a second heat dissipation element bonded with the first heat dissipation element and having a plurality of fins, wherein the second heat dissipation element can be made by extrusion, die casting, forging, folding, bonding, stamping, skiving, machining and metal injection molding etc. The first heat dissipation element is bonded with the second heat dissipation element by welding or thermal conductive adhesive.

A detailed description is given in the following embodiments with reference to the accompanying drawings.

### BRIEF DESCRIPTION OF THE DRAWINGS

The file of this patent contains at least one drawing/photograph executed in color. Copies of this patent with color drawing(s)/photograph(s) will be provided by the Office upon request and payment of the necessary fee.

The present invention can be more fully understood by reading the subsequent detailed description and examples with references made to the accompanying drawings, wherein:

FIGS. 1a and 1b are schematic views of a conventional heat dissipation device;

FIGS. 2a and 2b are schematic views of an embodiment of a heat dissipation device of the invention;

FIG. 3 is a picture of a conventional CPU heat sink with a copper base plate;

FIG. 4 is a picture of a CPU heat sink having a base plate of composite material with high thermal conductivity of the invention;

FIG. 5 is a picture of a conventional CPU heat sink with a copper base plate;

FIG. 6 is a picture of a CPU heat sink with a base plate of carbon fiber reinforced aluminum matrix composite of the invention;

FIG. 7 is a picture of a conventional laptop thermal module comprising a heat sink with a copper base plate;

FIG. 8 is a picture of a laptop thermal module comprising a heat sink with a base plate of carbon fiber reinforced aluminum matrix composite of the invention.

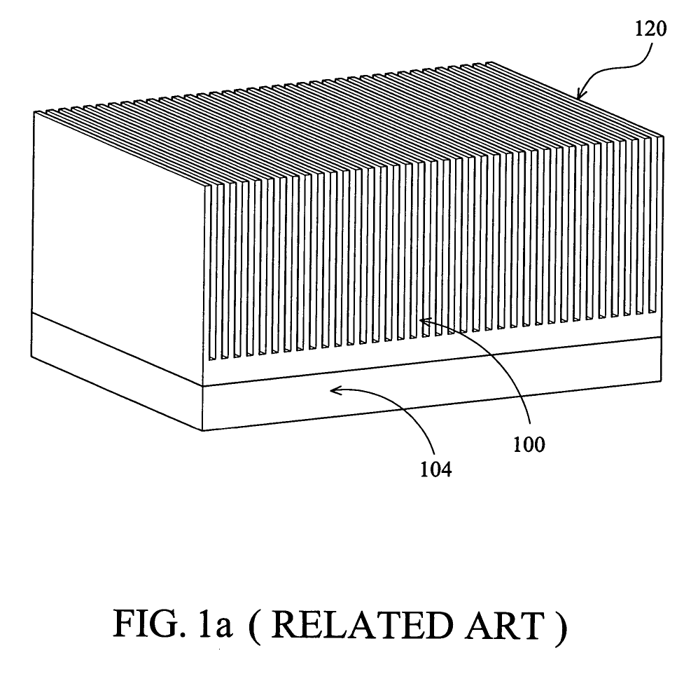

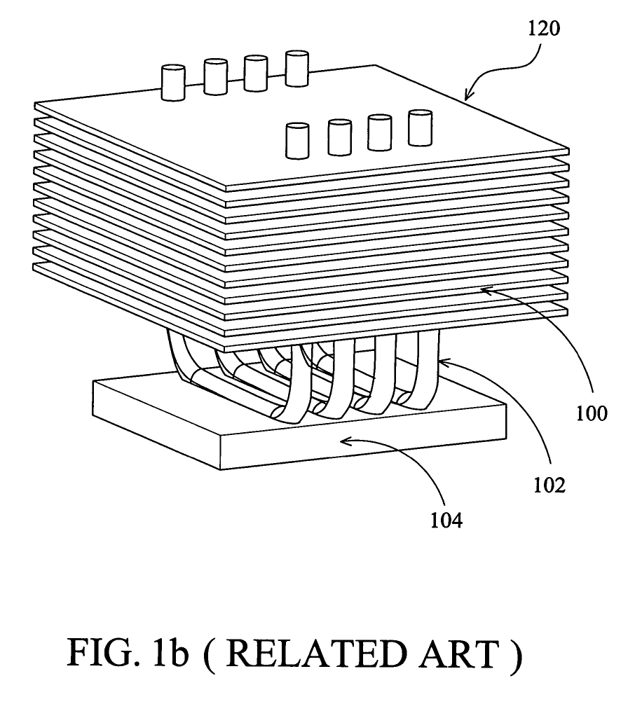

### DETAILED DESCRIPTION

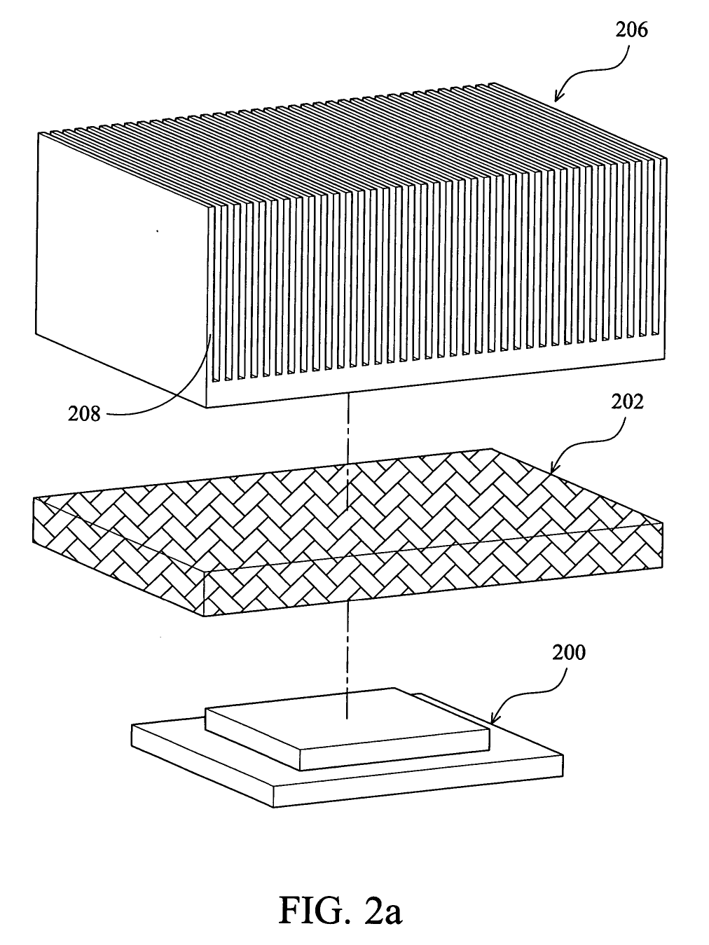

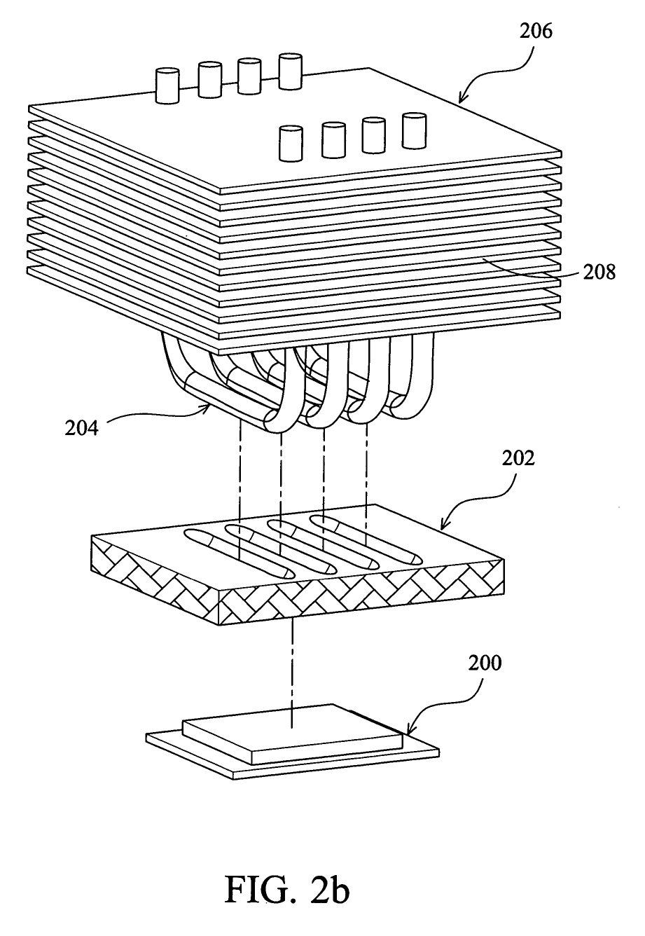

Referring to FIG. 2a, an embodiment of a heat sink comprises a first heat dissipation element (base plate) 202 and a second heat dissipation element 206. The first heat dissipation element 202 is directly mounted on an electronic element 200. The second heat dissipation element 206 comprises a plurality of fins 208 and joins the first heat dissipation element 202 by welding or thermal adhesive. Referring to FIG. 2b, the second heat dissipation element 206 further comprises a heat pipe 204 joined with the first heat dissipation element 202.

The first heat dissipation element 202 is made of a metal matrix composite reinforced with carbon fiber or graphite foam. The composite material has high thermal conductivity, low density, and thermal expansion coefficient matching semiconductor elements. The manufacture of the heat dissipation device of the invention is described as follows.

(1). The continuous carbon fibers are weaved into one dimensional, two dimensional or three dimensional form and immersed in resin or pitch to form a fiber perform after curing. The fiber preform is stabilized, carbonized and graphitized to yield a fibrous structure with high thermal conductivity. While the discontinuous graphite fibers are first dispersed in a stirred water solution and mixed with binders to form a carbon fiber perform by vacuum suction.

(2). Molten metal, such aluminum, copper, etc. or liquid pitch, is infiltrated into the fiber perform or graphite foam by high pressure or vacuum osmosis pressure to form a carbon fiber reinforced metal matrix or carbon matrix composite.

(3). The carbon fiber or graphite foam reinforced composite is cut into the predetermined sizes of the first heat dissipation element 202, which directly contact the heat-generating electronic element with/without a heat spreader.

(4). The surfaces of the first heat dissipation element 202 are coated with nickel, copper or silver in order to bond with the second heat dissipation element 206 or heat pipe 204.

(5). Solder is disposed on the top of the coated first heat dissipation element 202, and the first heat dissipation element 202 is joined to the second heat dissipation element 206.

Table 1 describes the material thermal properties of the composites of the invention, those include one dimensional, two dimensional or three dimensional carbon fiber reinforced aluminum and copper matrix composites. The thermal conductivity of those composites ranges from 260 to 800 W/m.K and the thermal diffusivity ranges from 1.246 to 5.18 cm²/s which is several times higher than the one of copper (1.05 cm²/s). Heat of the electronic element can be rapidly spread out and conducted to fins by this composite to avoid hot spots or overheating of electronic device. While the thermal expansion coefficient of those composites ranged from 2 to 10 ppm/K can be affordable with the one of semiconductor element (5˜6 ppm/K) in benefit of reducing thermal induced stress.

TABLE 1

| | | Thermal | | | Thermal |
|---|---|---|---|---|---|
| | | Conductivity | Thermal | Density | expansion |
| type | Volume % | (W/mK) (X-Y-Z) | Diffusivity (cm²/S) | (g/cc) | coefficient |
| 1D C—C/Al | 67% | 646/80/70 | 3.743/0.45/0.42 | 2.24 | 7.74 |
| 1D C—C/Al | 90% | 802/50/37 | 5.187/0.261/0.243 | 2.15 | 1.52 |
| 1D C—C/Cu | 67% | 717/100/86 | 3.012/0.142/0.126 | 4.2 | 4.162 |
| 2D C—C/Al | 80% | 320/310/150 | 1.63/1.57/0.78 | 2.27 | 4.02 |
| 3D C—C/Al | 85% | 330/320/190 | 1.84/1.80/1.16 | 2.28 | 3.4 |
| Graphite | 40˜60% | 260/252/245 | 1.246/0.92/0.853 | 2.4 | 10˜8 |
| foam/Al | | | | | |
| copper | 0 | 398 | 1.15 | 8.9 | 16 |
| aluminum | 0 | 220 | 0.96 | 2.68 | 23 |

One feature of the invention is that material of the first heat dissipation element 202 which contacts the semiconductor is a carbon fiber reinforced metal matrix composite having high thermal conductivity and high thermal diffusivity, which spreads heat generated by the electronic element rapidly. The heat is transferred to cold end via a heat pipe and a plurality of fins, and is dissipated to the external environment by a cooling fan or natural convection. Another feature is that the metal matrix composite of the invention has much lower density than copper in order to fabricate lighter heat dissipation elements. In another aspect, as the volume fraction of graphite or carbon fiber ranges from 30% to 90%, the thermal expansion coefficient of the composite material lies between 10˜2 ppm/K which can match the thermal expansion coefficient of semiconductor element (5˜6 ppm/K) and consequently reduce the thermal stress between the two different materials. The heat dissipation device of the invention has the advantages of light weight and good thermal performance. Several applications are described as follows.

Application 1

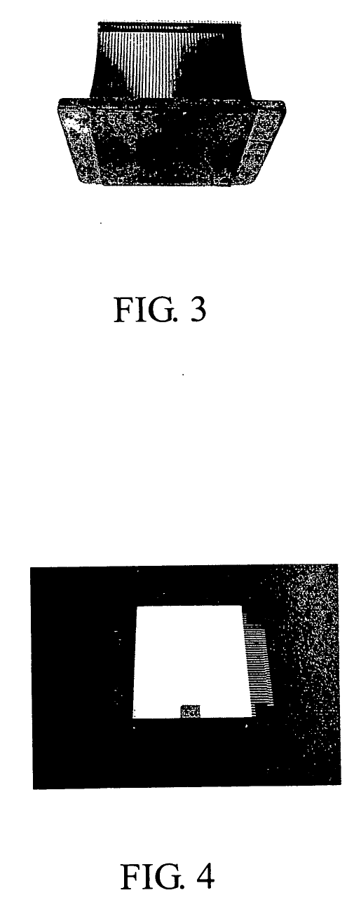

Copper based heat sinks instead of aluminum based heat sinks have been commonly used in many desktop CPUs with heat generation exceeding 100 W. FIG. 3 depicts a conventional heat sink with a copper base plate and stamped copper fins. The thermal resistance of this thermal module including a fan is 0.368° C./W with weight up to 580 g. While in this application, a heat dissipation device comprises a composite base plate and stamped aluminum fins where the composite base plate is made of carbon fiber reinforced aluminum matrix composite with high thermal conductivity as depicted in FIG. 4. The thermal resistance of this composite based heat dissipation device is 0.333□/W and the weight is only 192 g, much lighter than the conventional copper based heat sink as shown in table 2. This result proves that the heat dissipation device comprised the composite materials of the invention not only have good thermal performance, but also has light weight compared to the copper based heat sink.

TABLE 2

| Base plate | | Thermal | |
|---|---|---|---|
| material | Heat source | resistance | Weight |
| Copper | 89 W | 0.368° C./W | 580 g |
| Composite | 89.3 W | 0.333° C./W | 192 g |
| material | | | |

Application 2

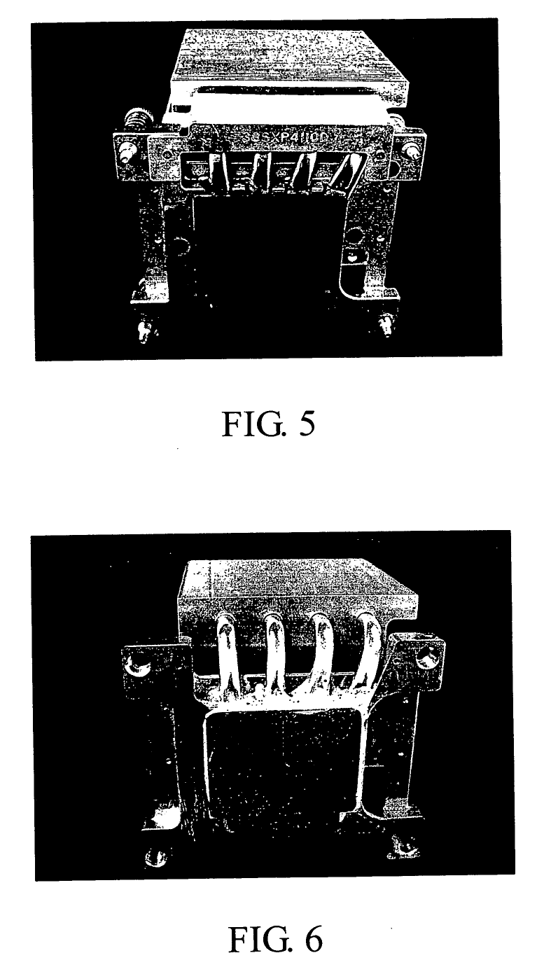

As the power dissipation of CPUs over 120 W, certain thermal modules integrating a copper base plate, heat pipe and fins (as shown in FIG. 5) are also designed to improve the thermal performance. In this invention, a heat dissipation device comprises a composite base plate heat pipe and stamped fins are assembled where the composite base plate is made of carbon fiber or graphite foam reinforced aluminum matrix composite. The composite material is coated with Ni or Cu and soldered to the heat pipes as shown in FIG. 6. Table 3 lists the thermal resistance of the application. The base plate made of composite material of the invention is 0.235° C./W, while the copper base plate is 0.269° C./W. That is because the composite base plate has lower thermal spreading resistance than copper base plate and the heat is rapidly conducted to the heat pipes, and to stamped fins.

TABLE 3

| Base plate | Heat | Junction | Ambient | Thermal |
|---|---|---|---|---|
| material | source | temperature | temperature | resistance |
| Copper | 126 W | 70.1° C. | 36.2° C. | 0.269° C./W |
| Composite | 126 W | 66.2° C. | 36.5° C. | 0.235° C./W |
| material | | | | |

Application 3

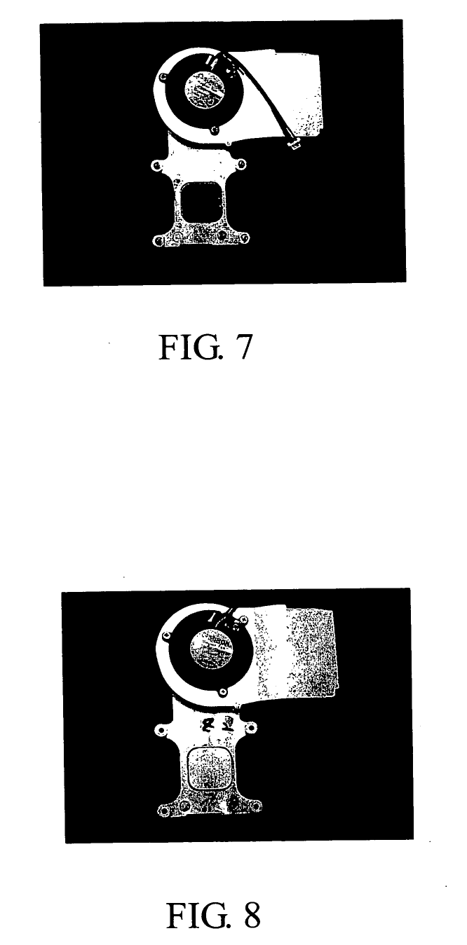

A thermal module of a laptop comprises a heat dissipation element, a heat pipe and a fan. The bottom of the heat dissipation element contacting the CPU is soldered to a copper plate as shown in FIG. 7. Even such a thermal module design has been popularly used in the current mobile CPU, but, however, an enhanced thermal module is required to meet the requirement of higher power dissipation (>30 W) in the future. In this application, a composite material of the invention is employed to replace the copper base plate of the thermal module as shown in FIG. 8. The heat generated by the mobile CPU can be rapidly spread and conducted to heat pipes due to the high thermal conductivity and high diffusivity of the composite base plate. This can avoid hot spots to occur. Table 4 shows the thermal resistance of the heat dissipation device of the invention which demonstrates that the thermal resistance of the invention comprised a composite base plate is lower than the one of the copper based thermal module. The base plate of composite material has thermal resistance 1.4° C./W and the copper base plate has thermal resistance 1.59° C./W.

TABLE 4

| Base | | | | |
|---|---|---|---|---|
| plate | Heat | Junction | Ambient | Thermal |
| material | source | temperature | temperature | resistance |
| Copper | 28.9 W | 81.88° C. | 36° C. | 1.59° C./W |
| Composite | 29.35 W | 78.45° C. | 37.3° C. | 1.40° C./W |
| material | | | | |

While the invention has been described by way of examples and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat dissipation device for an electronic device, comprising a first heat dissipation element contacting the electronic device, wherein the material of the first heat dissipation element comprises a composite material with high thermal conductivity comprising carbon fiber or graphite foam.

2. The heat dissipation device as claimed in claim 1, wherein the material with high thermal conductivity comprises a fibrous structure and a matrix.

3. The heat dissipation device as claimed in claim 2, wherein the fibrous structure comprises milled, discontinuous fibers or continuous fibers.

4. The heat dissipation device as claimed in claim 2, wherein the fibrous structure comprises PAN, pitch, vapor grown carbon fiber (VGCF), carbon nanotube or graphite foam.

5. The heat dissipation device as claimed in claim 2, wherein volume fraction of the fibrous structure is between 10% and 90%.

6. The heat dissipation device as claimed in claim 2, wherein the matrix comprises metal material.

7. The heat dissipation device as claimed in claim 6, wherein the metal matrix comprises aluminum and aluminum alloys.

8. The heat dissipation device as claimed in claim 6, wherein the metal material comprises copper and copper alloys.

9. The heat dissipation device as claimed in claim 6, wherein the metal material comprises silver, zinc, magnesium and their alloys thereof.

10. The heat dissipation device as claimed in claim 2, wherein the matrix comprises carbon material which has precursors of pitch□resin or hydrocarbon gases.

11. The heat dissipation device as claimed in claim 1, further comprising a second heat dissipation element contacting the first heart dissipation element and having a plurality of fins, wherein the second heat dissipation element can be made by extrusion, die casting, stamping, forging, bonding, folding, skiving, metal power injection molding.

12. The heat dissipation device as claimed in claim 11, wherein the first heat dissipation element is joined with the second heat dissipation element by welding or thermal adhesive.

13. A composite material with high thermal conductivity for a heat dissipation device, comprising a fibrous structure and a matrix.

14. The composite material as claimed in claim 13, wherein the fibrous structure comprises milled, discontinuous fibers or continuous fibers.

15. The composite material as claimed in claim 13, wherein the fibrous structure comprises PAN, pitch, vapor grown carbon fiber, carbon nanotubes or porous graphite.

16. The composite material as claimed in claim 13, wherein volume fraction of the fibrous structure is between 10% and 90%.

17. The composite material as claimed in claim 13, wherein the matrix comprises metal material.

18. The composite material as claimed in claim 17, wherein the metal matrix comprises aluminum and aluminum alloys.

19. The composite material as claimed in claim 17, wherein the metal material comprises copper and copper alloys.

20. The composite material as claimed in claim 17, wherein the metal material comprises silver, zinc, magnesium and their alloys thereof.

21. The composition material as claimed in claim 13, wherein the matrix comprises carbon material which has precursors of pitch, resin or carbonaceous gases.
